(19) United States
(12) Patent Application Publication
(10) Pub. No.: US 2025/0246574 A1
(43) Pub. Date: Jul. 31, 2025

(54) ELECTRONICS PACKAGE WITH SUBSTRATE RECESS AND CIRCUITRY COMPONENTS INTERCONNECTED OVER THE SUBSTRATE RECESS

(71) Applicant: Skyworks Solutions, Inc., Irvine, CA (US)

(72) Inventors: Andrew Christopher Laib, Newark, CA (US); Howard E. Chen, Anaheim, CA (US)

(21) Appl. No.: 19/038,456

(22) Filed: Jan. 27, 2025

Related U.S. Application Data
(60) Provisional application No. 63/626,372, filed on Jan. 29, 2024.

(51) Int. Cl. H01L 23/00; H01L 23/13; H01L 23/538; H01L 25/00; H01L 25/07; H01Q 1/22

(52) U.S. Cl. CPC H01L 24/48; H01L 23/13; H01L 25/072; H01Q 1/2283; H01L 23/5385; H01L 24/16; H01L 24/73; H01L 25/50; H01L 2224/16227; H01L 2224/48111; H01L 2224/48137; H01L 2224/73257

(57) ABSTRACT

An electronics package has a recess formed in the top surface of a substrate, with a first die mounted on a bottom surface of the recess, a second die mounted on the top surface of the substrate adjacent to the recess, and a third die mounted on the top surface of the substrate adjacent to the recess opposite to the second die. A wirebond spans over the first die and interconnecting the second die and the third die.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field of the Disclosure

Some embodiments disclosed herein relate to electronic packages suitable for coupling to a circuit board. The present disclosure also relates to a wireless electronic device incorporating such an electronic package. The present disclosure also relates to methods of manufacturing such an electronic package.

### Description of the Related Art

Conventional electronic packages have a substrate, with one or more electronic components or modules mounted to at least one side of the substrate. The electronic components/modules are mounted to the substrate by known methods of surface mounting technology.

In radio-frequency (RF) applications, RF circuits and related devices can be implemented in an electronics package. Such an electronics package can then be mounted on a circuit board such as a phone board.

Generally, most electronics packages for RF applications have a number of filter components, circuitry components in flip-chip (FC) orientation, or other surface mounted (SMT) components. For some electronics packages with a higher number of components, for example in electronics packages with a fairly high filter density, the lateral extensions of the package in the surface plane of the substrate may become quite large.

Although there are possibilities to reduce the footprint of an electronics package, for example by placing some circuitry components on the opposite side of the substrate, there remains a need for alternative solutions reducing the lateral extensions of an electronics package with a high number of surface mounted circuitry components.

### SUMMARY OF CERTAIN INVENTIVE ASPECTS

In some aspects, the techniques described herein relate to an electronics package, including: a substrate having a top surface and a recess formed in the top surface of the substrate; a first die mounted on a bottom surface of the recess; and a second die mounted on the top surface of the substrate adjacent to the recess so that at least a portion of the second die forms an overhang over the first die.

In some aspects, the techniques described herein relate to an electronics package wherein the first die is a filter chip, a surface mount technology component, or a flip-chip package.

In some aspects, the techniques described herein relate to an electronics package wherein the second die is a filter chip, a surface mount technology component, or a flip-chip package.

In some aspects, the techniques described herein relate to an electronics package wherein a thickness of the second die is greater than a thickness of the first die.

In some aspects, the techniques described herein relate to an electronics package wherein the first die is attached to the bottom surface of the recess by solder bumps.

In some aspects, the techniques described herein relate to an electronics package wherein the second die is attached to the top surface of the substrate by solder bumps.

In some aspects, the techniques described herein relate to an electronics package further including a third die mounted on the top surface of the substrate adjacent to the recess opposite to the second die so that at least a portion of the third die forms an overhang over the first die.

In some aspects, the techniques described herein relate to an electronics package wherein the third die is a filter chip, a surface mount technology component, or a flip-chip package.

In some aspects, the techniques described herein relate to an electronics package wherein a thickness of the third die is greater than the thickness of the first die.

In some aspects, the techniques described herein relate to an electronics package wherein the substrate includes a printed circuit board (PCB).

In some aspects, the techniques described herein relate to an electronics package wherein the substrate includes two layers of printed circuit boards stacked on top of each other, the two layers including an upper layer printed circuit board having a cutout forming the recess.

In some aspects, the techniques described herein relate to an electronics package wherein the substrate includes a single printed circuit board, the recess being formed as a cavity in the top surface of the printed circuit board.

In some aspects, the techniques described herein relate to an electronics package further including a fourth die mounted on the substrate between the top surface of the substrate and the second die.

In some aspects, the techniques described herein relate to an electronics package further including a third die mounted on the top surface of the substrate adjacent to the recess opposite to the second die so that at least a portion of the third die forms an overhang over the first die.

In some aspects, the techniques described herein relate to an electronics package further including a fifth die mounted on the substrate between the top surface of the substrate and the third die.

In some aspects, the techniques described herein relate to an electronics package further including a wirebond interconnecting a top surface of the second die and a top surface of the third die.

In some aspects, the techniques described herein relate to an electronics package wherein top surfaces of the second die and the third die stand out further from the top surface of the substrate than a top surface of the first die.

In some aspects, the techniques described herein relate to an electronics package wherein the second die is mounted on top of the fourth die by a die attach film.

In some aspects, the techniques described herein relate to an electronics package wherein the third die is mounted on top of the fifth die by a die attach film.

In some aspects, the techniques described herein relate to an electronics package, including: a substrate having a top surface and a recess formed in the top surface of the substrate; a first die mounted on a bottom surface of the recess; a second die mounted on the top surface of the substrate adjacent to the recess; a third die mounted on the top surface of the substrate adjacent to the recess opposite to the second die; and a wirebond spanning over the first die and interconnecting the second die and the third die.

In some aspects, the techniques described herein relate to an electronics package wherein the first die is a filter chip, a surface mount technology component, or a flip-chip package.

In some aspects, the techniques described herein relate to an electronics package wherein the second die is a filter chip, a surface mount technology component, or a flip-chip package.

In some aspects, the techniques described herein relate to an electronics package wherein a thickness of the second die is greater than the thickness of the first die.

In some aspects, the techniques described herein relate to an electronics package wherein the first die is attached to the bottom surface of the recess by solder bumps.

In some aspects, the techniques described herein relate to an electronics package wherein the second die is attached to the top surface of the substrate by solder bumps.

In some aspects, the techniques described herein relate to an electronics package wherein the substrate includes a printed circuit board (PCB).

In some aspects, the techniques described herein relate to an electronics package wherein the substrate includes two layers of printed circuit boards stacked on top of each other, the two layers including an upper layer printed circuit board having a cutout forming the recess.

In some aspects, the techniques described herein relate to an electronics package wherein the substrate includes a single printed circuit board, the recess being formed as a cavity in the top surface of the single printed circuit board.

In some aspects, the techniques described herein relate to an electronics package wherein top surfaces of the second die and the third die stand out further from the top surface of the substrate than a top surface of the first die.

In some aspects, the techniques described herein relate to an electronics package wherein at least a portion of the second die forms an overhang over the first die.

In some aspects, the techniques described herein relate to an electronics package wherein at least a portion of the third die forms an overhang over the first die.

In some aspects, the techniques described herein relate to a wireless electronic device, including: an antenna; and a circuit board including one or more electronics packages, the one or more electronics packages including a substrate having a top surface and a recess formed in the top surface of the substrate, a first die mounted on a bottom surface of the recess, and a second die mounted on the top surface of the substrate adjacent to the recess so that at least a portion of the second die forms an overhang over the first die.

In some aspects, the techniques described herein relate to a wireless electronic device wherein the first die is a filter chip, a surface mount technology component, or a flip-chip package.

In some aspects, the techniques described herein relate to a wireless electronic device wherein the second die is a filter chip, a surface mount technology component, or a flip-chip package.

In some aspects, the techniques described herein relate to a wireless electronic device wherein a thickness of the second die is greater than the thickness of the first die.

In some aspects, the techniques described herein relate to a wireless electronic device wherein the first die is attached to the bottom surface of the recess by solder bumps.

In some aspects, the techniques described herein relate to a wireless electronic device wherein the second die is attached to the top surface of the substrate by solder bumps.

In some aspects, the techniques described herein relate to a wireless electronic device further including a third die mounted on the top surface of the substrate adjacent to the recess opposite to the second die so that at least a portion of the third die forms an overhang over the first die.

In some aspects, the techniques described herein relate to a wireless electronic device wherein the third die is a filter chip, a surface mount technology component, or a flip-chip package.

In some aspects, the techniques described herein relate to a wireless electronic device wherein a thickness of the third die is greater than the thickness of the first die.

In some aspects, the techniques described herein relate to a wireless electronic device wherein the substrate includes a printed circuit board (PCB).

In some aspects, the techniques described herein relate to a wireless electronic device wherein the substrate includes two layers of printed circuit boards stacked on top of each other, the two layers including an upper layer printed circuit board having a cutout forming the recess.

In some aspects, the techniques described herein relate to a wireless electronic device wherein the substrate includes a single printed circuit board, the recess being formed as a cavity in the top surface of the printed circuit board.

In some aspects, the techniques described herein relate to a wireless electronic device further including a fourth die mounted on the substrate between the top surface of the substrate and the second die.

In some aspects, the techniques described herein relate to a wireless electronic device further including a third die mounted on the top surface of the substrate adjacent to the recess opposite to the second die so that at least a portion of the third die forms an overhang over the first die.

In some aspects, the techniques described herein relate to a wireless electronic device further including a fifth die mounted on the substrate between the top surface of the substrate and the third die.

In some aspects, the techniques described herein relate to a wireless electronic device further including a wirebond interconnecting a top surface of the second die and a top surface of the third die.

In some aspects, the techniques described herein relate to a wireless electronic device wherein top surfaces of the second die and the third die stand out further from the top surface of the substrate than a top surface of the first die.

In some aspects, the techniques described herein relate to a wireless electronic device wherein the second die is mounted on top of the fourth die by a die attach film.

In some aspects, the techniques described herein relate to a wireless electronic device wherein the third die is mounted on top of the fifth die by a die attach film.

In some aspects, the techniques described herein relate to a wireless electronic device, including: an antenna; and: a circuit board including one or more electronics packages, the one or more electronics packages including a substrate having a top surface and a substrate having a top surface and a recess formed in the top surface of the substrate, a first die mounted on a bottom surface of the recess, a second die mounted on the top surface of the substrate adjacent to the recess, a third die mounted on the top surface of the substrate adjacent to the recess opposite to the second die, and a wirebond spanning over the first die and interconnecting the second die and the third die.

In some aspects, the techniques described herein relate to a wireless electronic device wherein the first die is a filter chip, a surface mount technology component, or a flip-chip package.

In some aspects, the techniques described herein relate to a wireless electronic device wherein the second die is a filter chip, a surface mount technology component, or a flip-chip package.

In some aspects, the techniques described herein relate to a wireless electronic device wherein a thickness of the second die is greater than the thickness of the first die.

In some aspects, the techniques described herein relate to a wireless electronic device wherein the first die is attached to the bottom surface of the recess by solder bumps.

In some aspects, the techniques described herein relate to a wireless electronic device wherein the second die is attached to the top surface of the substrate by solder bumps.

In some aspects, the techniques described herein relate to a wireless electronic device wherein the substrate includes a printed circuit board (PCB).

In some aspects, the techniques described herein relate to a wireless electronic device wherein the substrate includes two layers of printed circuit boards stacked on top of each other, the two layers including an upper layer printed circuit board having a cutout forming the recess.

In some aspects, the techniques described herein relate to a wireless electronic device wherein the substrate includes a single printed circuit board, the recess being formed as a cavity in the top surface of the single printed circuit board.

In some aspects, the techniques described herein relate to a wireless electronic device wherein top surfaces of the second die and the third die stand out further from the top surface of the substrate than a top surface of the first die.

In some aspects, the techniques described herein relate to a wireless electronics device wherein at least a portion of the second die forms an overhang over the first die.

In some aspects, the techniques described herein relate to a wireless electronics device wherein at least a portion of the third die forms an overhang over the first die.

In some aspects, the techniques described herein relate to a method for manufacturing an electronics package, the method including: forming a recess in a top surface of a substrate; mounting a first die on a bottom surface of the recess; and mounting a second die on the top surface of the substrate adjacent to the recess so that at least a portion of the second die forms an overhang over the first die.

In some aspects, the techniques described herein relate to a method wherein the first die is a filter chip, a surface mount technology component, or a flip-chip package.

In some aspects, the techniques described herein relate to a method wherein the second die is a filter chip, a surface mount technology component, or a flip-chip package.

In some aspects, the techniques described herein relate to a method wherein a thickness of the second die is greater than the thickness of the first die.

In some aspects, the techniques described herein relate to a method wherein mounting the first die on a bottom surface of the recess includes attaching the first die to the bottom surface of the recess by solder bumps.

In some aspects, the techniques described herein relate to a method wherein mounting the second die to the top surface of the substrate includes attaching the second die to the top surface of the substrate by solder bumps.

In some aspects, the techniques described herein relate to a method further including mounting a third die on the top surface of the substrate adjacent to the recess opposite to the second die so that at least a portion of the third die forms an overhang over the first die.

In some aspects, the techniques described herein relate to a method wherein the third die is a filter chip, a surface mount technology component, or a flip-chip package.

In some aspects, the techniques described herein relate to a method wherein a thickness of the third die is greater than the thickness of the first die.

In some aspects, the techniques described herein relate to a method wherein the substrate includes a printed circuit board (PCB).

In some aspects, the techniques described herein relate to a method wherein the substrate includes two layers of printed circuit boards stacked on top of each other, and forming the recess includes excising a cutout from an upper layer printed circuit board of the two layers.

In some aspects, the techniques described herein relate to a method wherein the substrate includes a single printed circuit board, and forming the recess includes forming a cavity in the top surface of the printed circuit board.

In some aspects, the techniques described herein relate to a method further including mounting a fourth die on the substrate between the top surface of the substrate and the second die.

In some aspects, the techniques described herein relate to a method further including mounting a third die the top surface of the substrate adjacent to the recess opposite to the second die so that at least a portion of the third die forms an overhang over the first die.

In some aspects, the techniques described herein relate to a method further including mounting a fifth die on the substrate between the top surface of the substrate and the third die.

In some aspects, the techniques described herein relate to a method further including wirebonding a top surface of the second die and a top surface of the third die.

In some aspects, the techniques described herein relate to a method wherein top surfaces of the second die and the third die stand out further from the top surface of the substrate than a top surface of the first die.

In some aspects, the techniques described herein relate to a method wherein mounting the second die on top of the fourth die includes mounting the second die using a die attach film.

In some aspects, the techniques described herein relate to a method wherein mounting the third die on top of the fifth die includes mounting the third die using a die attach film.

In some aspects, the techniques described herein relate to a method wherein at least a portion of the second die forms an overhang over the first die.

In some aspects, the techniques described herein relate to a method wherein at least a portion of the third die forms an overhang over the first die.

In some aspects, the techniques described herein relate to a method for manufacturing an electronics package, the method including: forming a recess in a top surface of a substrate; mounting a first die on a bottom surface of the recess; mounting a second die on the top surface of the substrate adjacent to the recess; mounting a third die on the top surface of the substrate adjacent to the recess opposite to the second die; and spanning a wirebond over the first die to interconnect the second die and the third die.

In some aspects, the techniques described herein relate to a method wherein the first die is a filter chip, a surface mount technology component, or a flip-chip package.

In some aspects, the techniques described herein relate to a method wherein the second die is a filter chip, a surface mount technology component, or a flip-chip package.

In some aspects, the techniques described herein relate to a method wherein a thickness of the second die is greater than a thickness of the first die.

In some aspects, the techniques described herein relate to a method wherein mounting the first die on the bottom surface of the recess includes attaching the first die to the bottom surface of the recess by solder bumps.

In some aspects, the techniques described herein relate to a method wherein mounting the second die on the top surface of the substrate includes attaching the second die to the top surface of the substrate by solder bumps.

In some aspects, the techniques described herein relate to a method wherein the substrate includes a printed circuit board (PCB).

In some aspects, the techniques described herein relate to a method wherein the substrate includes two layers of printed circuit boards stacked on top of each other, and forming the recess includes excising a cutout from an upper layer printed circuit board of the two layers.

In some aspects, the techniques described herein relate to a method wherein the substrate includes a single printed circuit board, and forming the recess includes forming a cavity in the top surface of the single printed circuit board.

In some aspects, the techniques described herein relate to a method wherein top surfaces of the second die and the third die stand out further from the top surface of the substrate than a top surface of the first die.

### BRIEF DESCRIPTION OF THE DRAWINGS

Embodiments of this disclosure will now be described, by way of non-limiting example, with reference to the accompanying drawings, like reference numerals can refer to similar features throughout.

FIG. 1 depicts a cross-section view of an example embodiment of an electronics package.

FIG. 2 depicts a cross-section view of another example embodiment of an electronics package.

FIG. 3 depicts a cross-section view of another example embodiment of an electronics package.

FIG. 4 shows an example embodiment of a process for manufacturing an electronics package, such as the electronics package of any of the FIGS. 1 to 3.

FIG. 5 shows another example embodiment of a process for manufacturing an electronics package, such as the electronics package of any of the FIGS. 1 to 3.

FIG. 6 shows one or more of modules that are mounted on a wireless phone board that can include an electronics package having one or more features described herein.

FIG. 7 schematically depicts a circuit board with an electronics package having one or more features described herein installed thereon.

FIG. 8 schematically depicts a wireless device having the circuit board with an electronics package having one or more features described herein installed thereon.

FIG. 9 is a schematic diagram of one example of a communication network.

FIG. 10 is a schematic diagram of one embodiment of a mobile device.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

The positions and directions described herein may be described in relation to the orientations illustrated in the Figures, and in some cases the illustrated devices could be positioned in different orientations during use. For example, in some instances a substrate is shown at the bottom of a device, and the substrate could still be considered the bottom of the device even if it were installed in an inverted configuration.

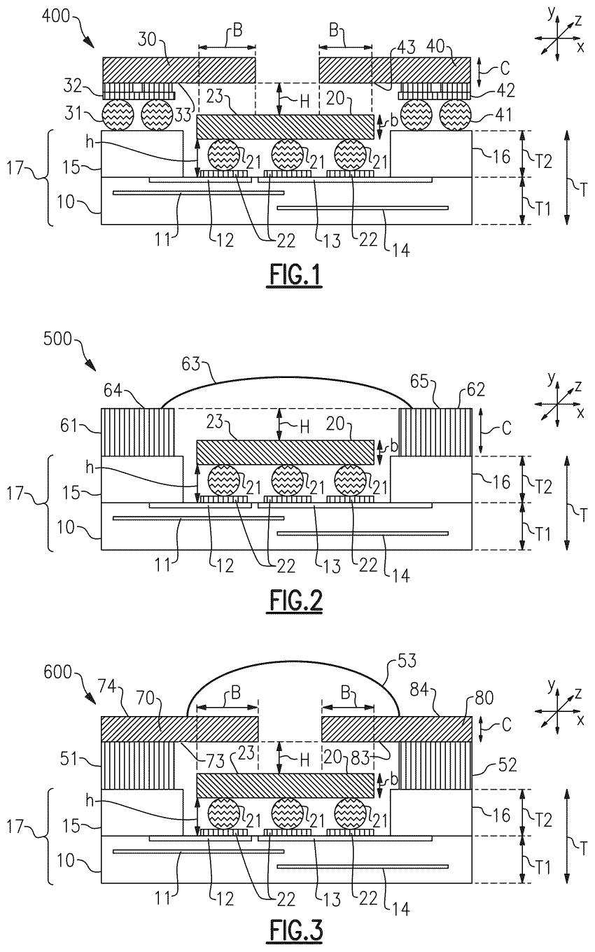

FIGS. 1, 2, and 3 schematically illustrate electronics packages 400, 500, and 600, respectively, in cross-section view. Each of the electronics packages 400, 500, and 600 includes a substrate 17. The substrate 17 may be generally plane, i.e. it may have a generally flat first surface (without limitation of generality, indicated as top surface in FIGS. 1, 2, and 3) and a generally flat second surface (without limitation of generality, indicated as bottom surface in FIGS. 1, 2, and 3) opposite to the first surface. The substrate 17 has a lateral extension in a plane parallel to the planes of the top and bottom surfaces, generally denoted as x-z-plane, with x being depicted as the direction from left to right on the drawing plane, y being depicted as the direction from bottom to top on the drawing plane, and z being the direction perpendicular to the drawing plane.

The role of the substrate 17 is to provide the interconnections to form at least a portion of an electric circuit. In some implementations, the substrate 17 may be a printed circuit board (PCB) or some other board mechanically supporting and electrically connecting electrical components mounted thereon using conductive tracks, pads and other features laminated onto and/or into the substrate 17. Such conductive tracks are exemplarily shown as features 11, 12, 13, and 14 in FIGS. 1, 2, and 3. In some implementations, a system-in-package (SiP) comprises a number of integrated circuits (ICs) mounted on such a substrate 17 and enclosed in a single electronics package 400, 500, or 600. The integrated circuits in the SiP can be internally connected by fine wires that are bonded to the package 400, 500, or 600. In some implementations, a system-on-chip (SoC) comprises an integrated circuit (IC) that integrates one or more components of an electronic system into a single substrate 17. In some implementations, a multi-chip module (MCM) comprises an electronic assembly that includes multiple integrated circuits (ICs), semiconductor dies and/or other discrete components integrated onto a unifying substrate 17.

Referring back to FIG. 1, the substrate 17 of the electronics package 400 includes a recess which is formed into the depth of the substrate 17 from the top surface. The recess may for example be essentially rectangular in cross-section and penetrate with a recess depth T2 into the substrate 17. The substrate 17 may, in some implementations, be a printed circuit board (PCB). In some cases, the substrate 17 includes two layers of PCBs stacked on top of each other. The bottom layer 10 may have a thickness T1 so that the overall thickness T of the substrate 17 is T1+T2. The upper layer PCB may include a cutout forming the recess between two edge portions 15 and 16, respectively, of the upper layer PCB. In other implementations, the substrate includes a single PCB. In such cases, the recess may be formed as a cavity in the top surface of the PCB down to a recess depth T2.

In some implementations, the top substrate portions 15 and 16 form a recess (e.g., a cavity or gap) over at least a bottom portion 10 of the substrate 17. The recess can be formed using a sacrificial layer, such as using polysilicon, or any other suitable material that can be removed during the manufacturing process to create the recess. The recess can elevate one or more layers on top of the top substrate portions 15 and 16 to at least partially define a top surface of the overall substrate 17

A first die 20 is mounted on the bottom surface of the recess, for example by means of solder bumps 21 attached to bump pads 22 on the bottom surface of the recess so that the height of the bottom surface of the first die 20 over the bottom surface of the recess is h. The first die 20 may for example be a filter chip, a surface mount technology (SMT) component, or a flip-chip package. Generally spoken, the first die 20 may be a chip that has a smaller footprint and may therefore more easily be lowered into the recess without protruding too far over the top surface of the substrate 17.

In various examples through the specification, flip chips are described herein as being mounted with solder bumps, such as the solder bumps 21 in FIG. 1. However, it will be understood that one or more features of the present disclosure can also be implemented utilizing other mounting structures, such as conductive pillars (e.g., copper pillars).

A second die 30 is mounted on the top surface of the substrate 17 adjacent to the recess. The second die 30 may for example be a filter chip, a surface mount technology (SMT) component, or a flip-chip package. For example, the second die 30 may be equipped with a metallization contact layer 32 on its bottom surface 33 so that it may be attached to the substrate 17 by solder bumps 31. Without limitation of generality, the second die 30 is shown to be attached to the upper portion 15 of the substrate 17 at the left edge of the recess, however, it should be understood that the second die 30 may be attached at any edge portion of the recess on the top surface of the substrate 17.

The second die 30 is mounted in such a way that at least a portion of the second die 30 forms an overhang over the first die 20. For example, as illustrated in FIG. 1, a side portion of the right side of the second die 30 having the width B overhangs the first die 20 partially, with a gap of height H between a bottom surface 33 of the second die 30 and a top surface 23 of the first die 20. Generally spoken, the second die 30 may be a chip that has a comparably larger footprint (than, for example, the first die 20) and may therefore protrude further over the area used to mount the second die 30 on the top surface of the substrate 17. Also, a thickness c of the second die 30 may in some implementations be greater than a thickness b of the first die 20. By mounting the second die 30 with an overhang over the first die 20, the overall lateral extension in the x-z plane of the electronics package 400 may be advantageously reduced as compared to a conventional electronics package in which the dies are placed on the substrate side-by-side.

In a similar manner to the second die 30, the electronics package 400 of FIG. 1 may include a third die 40 mounted on the top surface of the substrate 17 adjacent to the recess. The third die 40 may for example be a filter chip, a surface mount technology (SMT) component, or a flip-chip package. For example, the third die 40 may be equipped with a metallization contact layer 42 on its bottom surface 43 so that it may be attached to the substrate 17 by solder bumps 41. Without limitation of generality, the third die 40 is shown to be attached to the upper portion 16 of the substrate 17 at the right edge of the recess, however, it should be understood that the third die 40 may be attached at any edge portion of the recess on the top surface of the substrate 17 opposite to the second die 30. The third die 40 is mounted in such a way that at least a portion of the third die 40 forms an overhang over the first die 20. For example, as illustrated in FIG. 1, a side portion of the left side of the third die 40 having the width B overhangs the first die 20 partially, with a gap of height H between a bottom surface 43 of the third die 40 and a top surface 23 of the first die 20. Generally spoken, the third die 40 may be a chip that has a comparably larger footprint (than, for example, the first die 20) and may therefore protrude further over the area used to mount the third die 40 on the top surface of the substrate 17.

Also, a thickness c of the third die 40 may in some implementations be greater than a thickness b of the first die 20. Although being depicted with equal overhang widths B and equal thicknesses c, the second die 30 and the third die 40 may have different length, width, and/or thickness, and may be arranged so that the amount of overhang over the first die 20 is different for each of the second die 30 and the third die 40. The top surfaces of the second die 30 and the third die 40 stand out further from the top surface of the substrate 17 than a top surface of the first die 20 so that a gap H is formed between the top surface of the first die 20 and the bottom surfaces 33 and 43 of the second die 30 and the third die 40, respectively. By mounting the third die 40 with an overhang over the first die 20, the overall lateral extension in the x-z plane of the electronics package 400 may even further be advantageously reduced as compared to a conventional electronics package in which the dies are placed on the substrate side-by-side.

As shown, the first die 20 in some embodiments may extend above the top surface of the substrate 17 in certain embodiments, thereby making use of the space defined by the undersides of the second die 30 and the third die 40. In other embodiments, the first die 20 does not extend beyond the top surface of the substrate 17 and is instead fully enclosed within the recess.

Referring to FIG. 2, an electronics package 500 is shown in cross-section view. The electronics package 500 is similar to the electronics package 400 in that it includes a recess formed in its substrate 17 and a first die 20 mounted on the bottom surface of the recess. The electronics package 500 includes a second die 61 mounted on the top surface of the substrate adjacent to the recess. The second die 61 may for example be a filter chip, a surface mount technology (SMT) component, or a flip-chip package. The second die 61 may be attached to the substrate 17 by any suitable attachment technology, such as for example solder bumps or die-attachment films (DAF). Without limitation of generality, the second die 61 is shown to be attached to the upper portion 15 of the substrate 17 at the left edge of the recess, however, it should be understood that the second die 61 may be attached at any edge portion of the recess on the top surface of the substrate 17.

The electronics package 500 includes a third die 62 mounted on the top surface of the substrate 17 adjacent to the recess and on an opposite side of the second die 61. The third die 62 may for example be a filter chip, a surface mount technology (SMT) component, or a flip-chip package. The third die 62 may be attached to the substrate 17 by any suitable attachment technology, such as for example solder bumps or die-attachment films (DAF). Without limitation of generality, the third die 62 is shown to be attached to the upper portion 16 of the substrate 17 at the right edge of the recess, however, it should be understood that the third die 62 may be attached at any edge portion of the recess on the top surface of the substrate 17 so that it is located opposite to the second die 61. The second die 61 and the third die 62 may have a thickness c so that the top surfaces 64 and 65 of the second die 61 and the third die 62, respectively, stand out higher from the substrate 17 than the top surface 23 of the first die 20. In other words, a gap of thickness H is present between the top surface 23 of the first die 20 and the virtual plane made up by the top surfaces 64 and 65 of the second die 61 and the third die 62.

A wirebond 63 spans over the recess and, incidentally, over the top surface 23 of the first die 20. The wirebond 63 interconnects the top surfaces 64 and 65 of the second die 61 and the third die 62, respectively. Although there is only a single wirebond 63 illustrated in FIG. 2, it should be understood that any number of wirebonds may be formed interconnecting the second die 61 and the third die 62. By wirebonding the second die 61 and the third die 62 over the first die 20, the overall lateral extension in the x-z plane of the electronics package 500 may be advantageously reduced as compared to a conventional electronics package in which the wirebonds of the dies need additional space to the side of the first die.

As shown, the first die 20 in some embodiments may extend above the top surface of the substrate 17 in certain embodiments, thereby making use of the space between the top surface of the substrate 17 and the virtual plane formed by the top surfaces 64 and 65 of the second die 61 and the third die 62. In other embodiments, the first die 20 does not extend beyond the top surface of the substrate 17 and is instead fully enclosed within the recess.

Referring to FIG. 3, an electronics package 600 is shown in cross-section view. The electronics package 600 is similar to the electronics package 400 in that it includes a recess formed in its substrate 17 and a first die 20 mounted on the bottom surface of the recess. The electronics package 600 includes a second die 70 similar to the second die 30 of the electronics package 400 of FIG. 1. The electronics package 600 includes a third die 80 similar to the third die 40 of the electronics package 400 of FIG. 1.

The electronics package 600 includes a fourth die 51 mounted on the substrate 17 between the top surface of the substrate 17 and the second die 70. For example, the second die 70 may be attached to the top surface of the fourth die 51 via a die-attach film (DAF). The electronics package 600 includes a fifth die 52 mounted on the substrate 17 between the top surface of the substrate 17 and the third die 80. For example, the third die 80 may be attached to the top surface of the fifth die 52 via a die-attach film (DAF). The fourth die 51 is mounted on a top surface of the substrate 17 adjacent to the recess so that at least a portion of the second die 70 forms an overhang over the first die 20. Similarly, the fifth die 52 is mounted on a top surface of the substrate 17 adjacent to the recess so that at least a portion of the third die 80 forms an overhang over the first die 20 opposite to the second die 70.

Without limitation of generality, the stack of the fourth die 51 and the second die 70 is shown to be attached to the upper portion 15 of the substrate 17 at the left edge of the recess, however, it should be understood that the stack of the fourth die 51 and the second die 70 may be attached at any edge portion of the recess on the top surface of the substrate 17. Similarly, and without limitation of generality, the stack of the fifth die 52 and the third die 80 is shown to be attached to the upper portion 16 of the substrate 17 at the right edge of the recess, however, it should be understood that the stack of the fifth die 52 and the third die 80 may be attached at any edge portion of the recess on the top surface of the substrate 17 opposite to the second die 30. The second die 70 and the third die 80 is mounted in such a way that at least portions of the second die 70 and the third die 80 form an overhang over the first die 20 from different sides. For example, as illustrated in FIG. 3, a side portion of the left side of the second die 70 having the width B overhangs the first die 20 partially, with a gap of height H between a bottom surface 73 of the second die 70 and a top surface 23 of the first die 20. Similarly, a side portion of the left side of the third die 80 having the width B overhangs the first die 20 partially, with a gap of height H between a bottom surface 83 of the third die 80 and a top surface 23 of the first die 20.

The second die 70, the third die 80, the fourth die 51, and the fifth die 52 may all be selected from a group comprising a filter chip, a surface mount technology (SMT) component, and a flip-chip package. The second die 70, the third die 80, the fourth die 51, and the fifth die 52 may have similar or different functions.

A wirebond 53 spans over the recess and, incidentally, over the top surface 23 of the first die 20. The wirebond 53 interconnects the top surfaces 74 and 84 of the second die 70 and the third die 80, respectively. Although there is only a single wirebond 53 illustrated in FIG. 3, it should be understood that any number of wirebonds may be formed interconnecting the second die 70 and the third die 80. By wirebonding the second die 70 and the third die 80 over the first die 20, the overall lateral extension in the x-z plane of the electronics package 600 may be advantageously reduced as compared to a conventional electronics package in which the wirebonds of the dies need additional space to the side of the first die.

As shown, the first die 20 in some embodiments may extend above the top surface of the substrate 17 in certain embodiments, thereby making use of the space defined by the undersides of the second die 70 and the third die 80. In other embodiments, the first die 20 does not extend beyond the top surface of the substrate 17 and is instead fully enclosed within the recess.

The electronics packages disclosed herein, such as for example the electronics packages 400, 500, and 600 as illustrated in and explained in conjunction with FIGS. 1, 2, and 3, can be made using any suitable techniques or processes. In some cases, material or layers can be deposited by any suitable technique, and select portions of the deposited material can be removed, such as by etching, while other portions of the deposited material can be retained, such as by shielding the material from etching using a mask. Various other manufacturing processes could be used. The circuit assemblies in the electronics packages described herein can further comprise an overmold structure formed of a molding material. The molding material may be pliable and moldable in process and becomes hard when cured. In some implementations, the overmold structure covers at least a portion of the top of the substrate and one or more components located on the top portion of the substrate, where the bottom surface of the substrate is free from the overmold structure in order to make electrical connections to the various circuitry components. In other implementations, the overmold structure covers at least a portion of the bottom surface of the substrate and one or more components located on the bottom of the substrate. Electrical connections to the circuit assemblies described herein may be made from the top of the substrate.

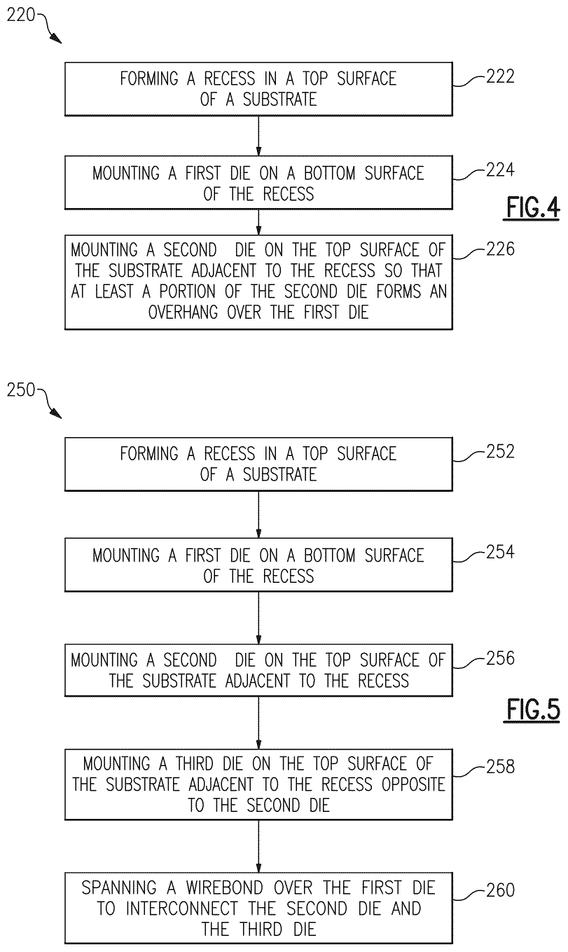

Two exemplary manufacturing processes for manufacturing an electronics package are shown schematically in FIGS. 4 and 5. The manufacturing processes depicted in FIGS. 4 and 5 may be used to manufacture electronics packages having one or more features as disclosed herein, for example in conjunction with FIGS. 1, 2 and/or 3. In a first manufacturing process 220 depicted in FIG. 4, a first step 222 involves forming a recess in a top surface of a substrate. A second step 224 involves mounting a first die on a bottom surface of the recess. A third step 226 involves mounting a second die on the top surface of the substrate adjacent to the recess so that at least a portion of the second die forms an overhang over the first die.

In a second manufacturing process 250 depicted in FIG. 5, a first step 252 involves forming a recess in a top surface of a substrate. A second step 254 involves mounting a first die on a bottom surface of the recess. A third step 256 involves mounting a second die on the top surface of the substrate adjacent to the recess. A fourth step 258 involves mounting a third die on the top surface of the substrate adjacent to the recess opposite to the second die. Finally, a fifth step 260 involves spanning a wirebond over the first die to interconnect the second die and the third die.

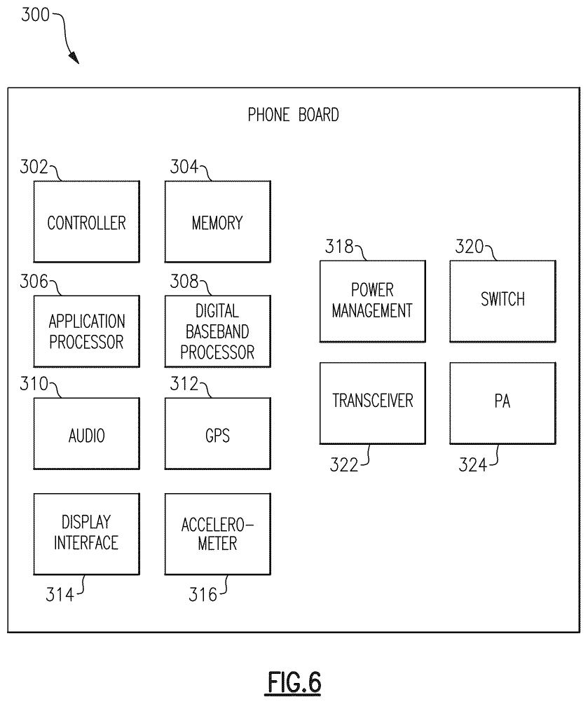

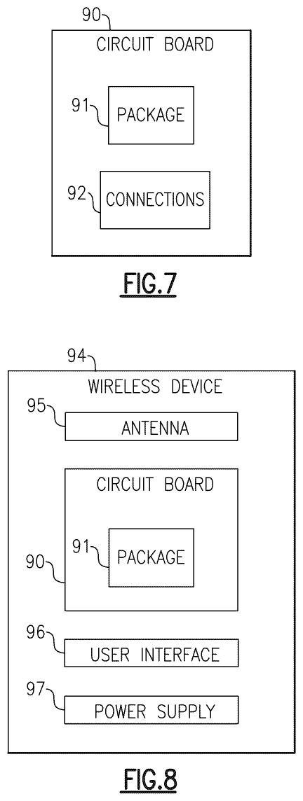

FIG. 6 shows that, in some embodiments, one or more modules included in a circuit board such as a wireless phone board 300 can include one or more electronics packages with dies, filters, SMTs, and/or chips mounted on a printed circuit board (PCB) as described herein. Non-limiting examples of modules that can benefit from such packaging features include, but are not limited to, a controller module 302, an application processor module 306, an audio module 310, a display interface module 314, a memory module 304, a digital baseband processor module 308, a global positioning system (GPS) module 312, an accelerometer module 316, a power management module 318, a transceiver module 322, a switching module 320, and a power amplifier module 324.

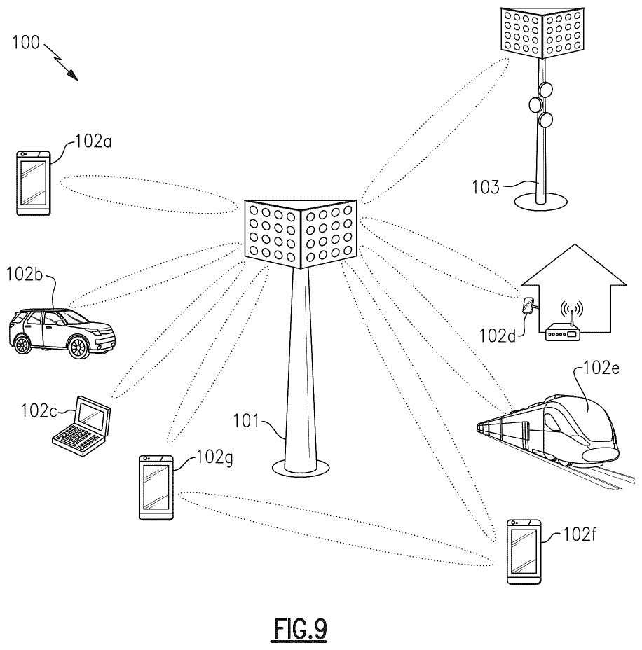

FIG. 7 schematically depicts a circuit board 90 having an electronics package 91 (e.g., die, SMT package, filter) mounted thereon in the manner described herein. The circuit board 90 can also include other features such as a plurality of connections 92 to facilitate operations of various electronics packages 91 mounted thereon. FIG. 8 schematically depicts a wireless electronic device 94 (e.g., a cellular phone) having a circuit board 90 (e.g., a phone board). The circuit board 90 is shown to include a package 91 (e.g., die, SMT package, filter) mounted thereon in the manner described herein. The wireless electronic device 94 is shown to further include other components, such as an antenna 95, a user interface 96, and a power supply 97.

FIG. 9 is a schematic diagram of one example of a communication network 100. The communication network 100 includes a macro cell base station 101, a small cell base station 103, and various examples of user equipment (UE), including a first mobile device 102a, a wirelessly connected car 102b, a laptop 102c, a stationary wireless device 102d, a wirelessly connected train 102e, a second mobile device 102f, and a third mobile device 102g.

Although specific examples of base stations and user equipment are illustrated in FIG. 9, a communication network 100 can include base stations and user equipment of a wide variety of types and/or numbers.

For instance, in the example shown, the communication network 100 includes the macro cell base station 101 and the small cell base station 103. The small cell base station 103 can operate with relatively lower power, shorter range, and/or with fewer concurrent users relative to the macro cell base station 101. The small cell base station 103 can also be referred to as a femtocell, a picocell, or a microcell. Although the communication network 100 is illustrated as including two base stations, the communication network 100 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 100 of FIG. 9 supports communications using a variety of cellular technologies, including, for example, 4G LTE and 5G NR. In certain implementations, the communication network 100 is further adapted to provide a wireless local area network (WLAN), such as WiFi. Although various examples of communication technologies have been provided, the communication network 100 can be adapted to support a wide variety of communication technologies.

Various communication links of the communication network 100 have been depicted in FIG. 9. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 9, the communication links include not only communication links between UE and base stations, but also UE to UE communications and base station to base station communications. For example, the communication network 100 can be implemented to support self-fronthaul and/or self-backhaul (for instance, as between mobile device 102g and mobile device 102f).

The communication links can operate over a wide variety of frequencies. In certain implementations, communications are supported using 5G NR technology over one or more frequency bands that are less than 6 Gigahertz (GHz) and/or over one or more frequency bands that are greater than 6 GHz. For example, the communication links can serve Frequency Range 1 (FR1) in the range of about 410 MHz to about 7.125 GHZ, Frequency Range 2 (FR2) in the range of about 24.250 GHz to about 52.600 GHz, or a combination thereof. In one embodiment, one or more of the mobile devices support a HPUE power class specification.

Different users of the communication network 100 can share available network resources, such as available frequency spectrum, in a wide variety of ways. In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 2 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 100 of FIG. 9 can be used to support a wide variety of advanced communication features, including, but not limited to, eMBB, uRLLC, and/or mMTC.

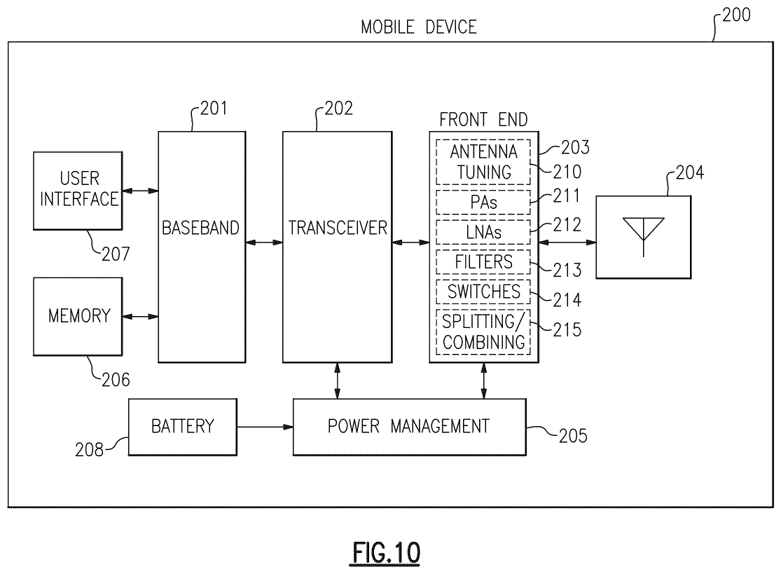

FIG. 10 is a schematic diagram of one embodiment of a mobile device 200. The mobile device 200 includes a baseband system 201, a transceiver 202, a front end system 203, antennas 204, a power management system 205, a memory 206, a user interface 207, and a battery 208.

The mobile device 200 can be used communicate using a wide variety of communications technologies, including, but not limited to, 2G, 3G, 4G (including LTE, LTE-Advanced, and LTE-Advanced Pro), 5G NR, WLAN (for instance, WiFi), WPAN (for instance, Bluetooth and ZigBee), WMAN (for instance, WiMax), and/or GPS technologies.

The transceiver 202 generates RF signals for transmission and processes incoming RF signals received from the antennas 204. It will be understood that various functionalities associated with the transmission and receiving of RF signals can be achieved by one or more components that are collectively represented in FIG. 10 as the transceiver 202. In one example, separate components (for instance, separate circuits or dies) can be provided for handling certain types of RF signals.

The front end system 203 aids in conditioning signals transmitted to and/or received from the antennas 204. In the illustrated embodiment, the front end system 203 includes antenna tuning circuitry 210, power amplifiers (PAS) 211, low noise amplifiers (LNAs) 212, filters 213, switches 214, and signal splitting/combining circuitry 215. However, other implementations are possible as well.

For example, the front end system 203 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 200 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 204 can include antennas used for a wide variety of types of communications. For example, the antennas 204 can include antennas for transmitting and/or receiving signals associated with a wide variety of frequencies and communications standards.

In certain implementations, the antennas 204 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 200 can operate with beamforming in certain implementations. For example, the front end system 203 can include amplifiers having controllable gain and phase shifters having controllable phase to provide beam formation and directivity for transmission and/or reception of signals using the antennas 204. For example, in the context of signal transmission, the amplitude and phases of the transmit signals provided to the antennas 204 are controlled such that radiated signals from the antennas 204 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 204 from a particular direction. In certain implementations, the antennas 204 include one or more arrays of antenna elements to enhance beamforming.

The baseband system 201 is coupled to the user interface 207 to facilitate processing of various user input and output (I/O), such as voice and data. The baseband system 201 provides the transceiver 202 with digital representations of transmit signals, which the transceiver 202 processes to generate RF signals for transmission. The baseband system 201 also processes digital representations of received signals provided by the transceiver 202. As shown in FIG. 10, the baseband system 201 is coupled to the memory 206 of facilitate operation of the mobile device 200.

The memory 206 can be used for a wide variety of purposes, such as storing data and/or instructions to facilitate the operation of the mobile device 200 and/or to provide storage of user information.

The power management system 205 provides a number of power management functions of the mobile device 200. In certain implementations, the power management system 205 includes a PA supply control circuit that controls the supply voltages of the power amplifiers 211. For example, the power management system 205 can be configured to change the supply voltage(s) provided to one or more of the power amplifiers 211 to improve efficiency, such as power added efficiency (PAE).

As shown in FIG. 10, the power management system 205 receives a battery voltage from the battery 208. The battery 208 can be any suitable battery for use in the mobile device 200, including, for example, a lithium-ion battery.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHZ. An electronics package including any suitable combination of features disclosed herein be included in a filter arranged to filter a radio frequency signal in a fifth generation (5G) New Radio (NR) operating band within Frequency Range 1 (FR1). A filter arranged to filter a radio frequency signal in a 5G NR operating band can include one or more electronics packages as disclosed herein. FR1 can be from 410 MHz to 7.125 GHz, for example, as specified in a current 5G NR specification. One or more electronics packages in accordance with any suitable principles and advantages disclosed herein can be included in a filter arranged to filter a radio frequency signal in a fourth generation (4G) Long Term Evolution (LTE) operating band and/or in a filter with a passband that spans a 4G LTE operating band and a 5G NR operating band.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. An electronics package, comprising:
a substrate having a top surface and a recess formed in the top surface of the substrate;
a first die mounted on a bottom surface of the recess;
a second die mounted on the top surface of the substrate adjacent to the recess;
a third die mounted on the top surface of the substrate adjacent to the recess opposite to the second die; and
a wirebond spanning over the first die and interconnecting the second die and the third die.

2. The electronics package of claim 1 wherein the first die is a filter chip, a surface mount technology component, or a flip-chip package, and the second die is a filter chip, a surface mount technology component, or a flip-chip package.

3. The electronics package of claim 1 wherein the first die is attached to the bottom surface of the recess by solder bumps.

4. The electronics package of claim 1 wherein the substrate includes two layers of printed circuit boards stacked on top of each other, the two layers including an upper layer printed circuit board having a cutout forming the recess.

5. The electronics package of claim 1 wherein at least a portion of the second die forms an overhang over the first die.

6. The electronics package of claim 5 wherein at least a portion of the third die forms an overhang over the first die.

7. A wireless electronic device, comprising:
an antenna; and:
a circuit board including one or more electronics packages, the one or more electronics packages including a substrate having a top surface and a substrate having a top surface and a recess formed in the top surface of the substrate, a first die mounted on a bottom surface of the recess, a second die mounted on the top surface of the substrate adjacent to the recess, a third die mounted on the top surface of the substrate adjacent to the recess opposite to the second die, and a wirebond spanning over the first die and interconnecting the second die and the third die.

8. The wireless electronic device of claim 7 wherein the first die is a filter chip, a surface mount technology component, or a flip-chip package.

9. The wireless electronic device of claim 8 wherein the second die is a filter chip, a surface mount technology component, or a flip-chip package.

10. The wireless electronic device of claim 9 wherein a thickness of the second die is greater than the thickness of the first die.

11. The wireless electronic device of claim 7 wherein the first die is attached to the bottom surface of the recess by solder bumps.

12. The wireless electronic device of claim 7 wherein the second die is attached to the top surface of the substrate by solder bumps.

13. The wireless electronic device of claim 7 wherein the substrate includes a printed circuit board (PCB).

14. The wireless electronic device of claim 13 wherein the substrate includes two layers of printed circuit boards stacked on top of each other, the two layers including an upper layer printed circuit board having a cutout forming the recess.

15. The wireless electronic device of claim 13 wherein the substrate includes a single printed circuit board, the recess being formed as a cavity in the top surface of the single printed circuit board.

16. The wireless electronic device of claim 7 wherein top surfaces of the second die and the third die stand out further from the top surface of the substrate than a top surface of the first die.

17. The wireless electronic device of claim 7 wherein at least a portion of the second die forms an overhang over the first die.

18. The wireless electronic device of claim 17 wherein at least a portion of the third die forms an overhang over the first die.

19. A method for manufacturing an electronics package, the method comprising:
forming a recess in a top surface of a substrate;
mounting a first die on a bottom surface of the recess;
mounting a second die on the top surface of the substrate adjacent to the recess;
mounting a third die on the top surface of the substrate adjacent to the recess opposite to the second die; and
spanning a wirebond over the first die to interconnect the second die and the third die.

20. The method of claim 19 wherein the first die is a filter chip, a surface mount technology component, or a flip-chip package, and the second die is a filter chip, a surface mount technology component, or a flip-chip package.
